(19) United States
(12) Patent Application Publication
(10) Pub. No.: US 2010/0139742 A1
(43) Pub. Date: Jun. 10, 2010

(54) Photovoltaic Module Assembly With Integrated Junctions

(76) Inventors: Elizabeth N. WAYMAN, Richmond, CA (US); Carl LENOX, Oakland, CA (US); Adam DETRICK, Petaluma, CA (US)

Correspondence Address: Okamoto & Benedicto LLP, P.O. Box 641330, San Jose, CA, 95164-1330, US

(21) Appl. No.: 12/577,423

(22) Filed: Oct. 12, 2009

(51) Int. Cl. H01L 31/048; H01L 31/18

(52) U.S. Cl. 136/251; 438/64; 438/64; 257/E31.117

(57) ABSTRACT

One embodiment relates to a photovoltaic (PV) module assembly with integrated junctions manufactured in a factory. The assembly includes a plurality of PV laminates and a frame surrounding and supporting each of the PV laminates in the module. A plurality of environmentally-protected electrical junctions interconnect the photovoltaic laminates. Another embodiment relates to a method of manufacturing a PV module assembly in which pin terminals of PV laminates are inserted into corresponding sockets of junction boxes that are integrated into a frame of the assembly. Another embodiment relates to a method of manufacturing a PV module assembly in which non-insulated conductors are extended from PV laminates, electrical junctions are formed between the conductors, and material is applied to encapsulate the junctions. Other embodiments and features are also disclosed.

### BACKGROUND OF THE INVENTION

1. Field of the Invention

The present invention relates generally to photovoltaic module assemblies.

2. Description of the Background Art

Photovoltaic (PV) cells, also referred to as “solar cells,” are well known devices for converting solar radiation to electrical energy. Photovoltaic cells may be packaged together in a photovoltaic module. The PV module may include a plurality of interconnected photovoltaic cells in a laminate, and an external junction box attached to the laminate, including leads and connectors which allow modules to be interconnected electrically.

PV modules are typically installed on a support structure at the installation site. The PV modules are typically then electrically interconnected with the leads from one module to the next in series, or to a common bus in parallel, or a combination of series and parallel connections.

### SUMMARY

One embodiment of the invention relates to a photovoltaic (PV) module assembly with integrated junctions. The assembly includes a plurality of PV laminates and a frame surrounding and supporting each of the PV laminates in the module. A plurality of environmentally-protected electrical junctions interconnect the photovoltaic laminates. The electrical interconnections are designed to be made in the factory, not the field, and may be permanent in that they are not designed to be disconnected.

Another embodiment relates to a method of manufacturing a PV module assembly in which pin terminals of PV laminates are inserted into corresponding sockets of junction boxes that are integrated into a frame of the assembly.

Another embodiment relates to a method of manufacturing a PV module assembly in which non-insulated conductors are extended from PV laminates, electrical junctions are formed between the conductors, and material is applied to encapsulate the junctions.

These and other embodiments and features of the present invention will be readily apparent to persons of ordinary skill in the art upon reading the entirety of this disclosure, which includes the accompanying drawings and claims.

### BRIEF DESCRIPTION OF THE DRAWINGS

FIG. 1 is a perspective view of a frame-integrated electrical junction for a PV module assembly in accordance with a first embodiment of the invention.

FIG. 2 is a top view of the frame-integrated electrical junction for a PV module assembly in accordance with the first embodiment of the invention.

FIG. 3 is an exploded view showing separate components of the frame-integrated electrical junction for a PV module assembly in accordance with the first embodiment of the invention.

FIG. 4 is a flow chart of a method of manufacturing a PV module assembly with a frame-integrated electrical junction in accordance with the first embodiment of the invention.

FIG. 5 is a cross-sectional view of a frame-integrated electrical junction for a PV module assembly in accordance with a second embodiment of the invention.

FIG. 6 is a flow chart of a method of manufacturing a PV module assembly with a frame-integrated electrical junction in accordance with the second embodiment of the invention.

The use of the same reference label in different drawings indicates the same or like components.

### DETAILED DESCRIPTION

In the present disclosure, numerous specific details are provided, such as examples of apparatus, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

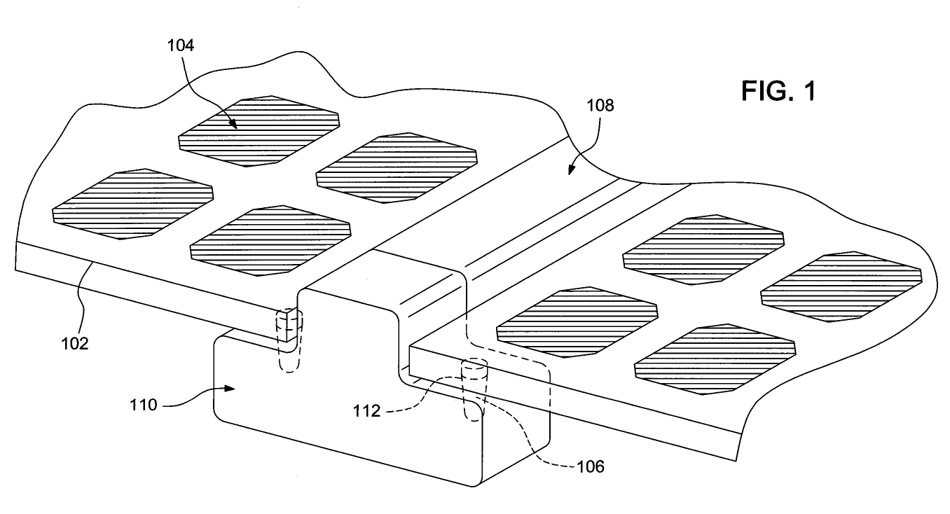

FIG. 1 is a perspective view of a frame-integrated electrical junction for a PV module assembly in accordance with a first embodiment of the invention. Shown in FIG. 1 are two PV laminates 102, each laminate 102 including a plurality of solar cells 104 and electrical connections between the solar cells. Bypass diodes may also be embedded within the PV laminates. The specific configuration for the electrical connections and bypass diodes within a PV laminate 102 depends on the specific implementation used.

As further shown, each PV laminate 102 includes at least one pin terminal 106. In one embodiment, each PV laminate 102 includes two pin terminals 106. Each pin terminal 106 is electrically connected within the PV laminate 102 to at least one of the solar cells 104. For example, a pin terminal 106 may be electrically connected to a solar cell 104 in a corner position within the PV laminate 102.

An inner frame member 108 of a frame for the PV module assembly is also shown in FIG. 1. As further shown, an electrical junction box 110 may be integrated within the inner frame member 108. The electrical junction box 110 includes at least two sockets 112. Each socket 112 is configured to receive a pin terminal 106 from a PV laminate 102 when the PV laminate 102 is inserted into the frame.

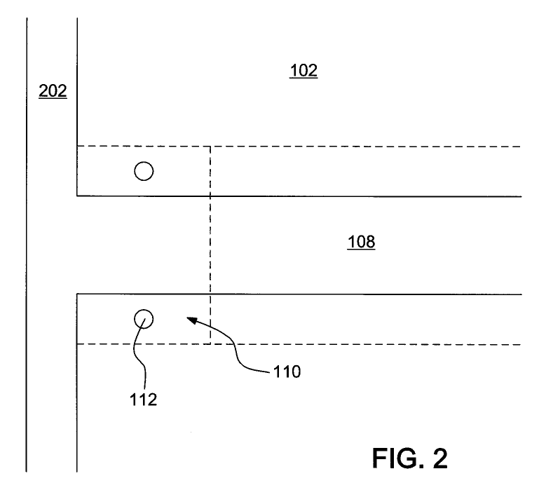

FIG. 2 is a top view of the frame-integrated electrical junction for a PV module assembly in accordance with the first embodiment of the invention. This top view shows a portion of the frame which includes part of an inner frame member 108 and part of an outer frame member 202 which are joined together. Two PV laminates 102 are shown, one positioned on each side of the inner frame member 108. The junction box 110 within the inner frame member 108 and the two sockets 112 of the junction box 110 are also shown.

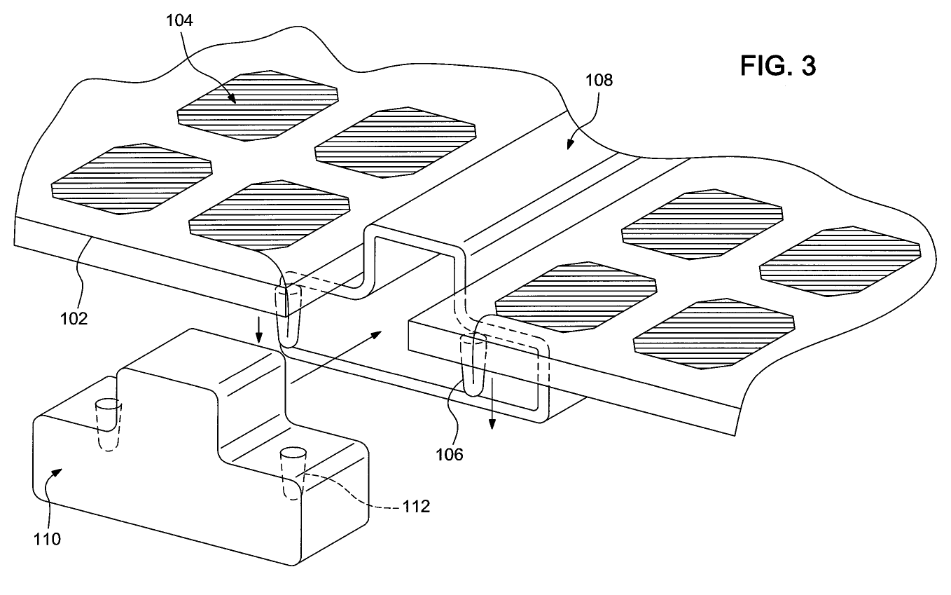

FIG. 3 is an exploded view showing separate components of the frame-integrated electrical junction for a PV module assembly in accordance with the first embodiment of the invention. The separate components shown are the PV laminates 102 (including solar cells 104 and the pin terminals 106), the inner frame member 108, and the junction box 110 (including the sockets 112).

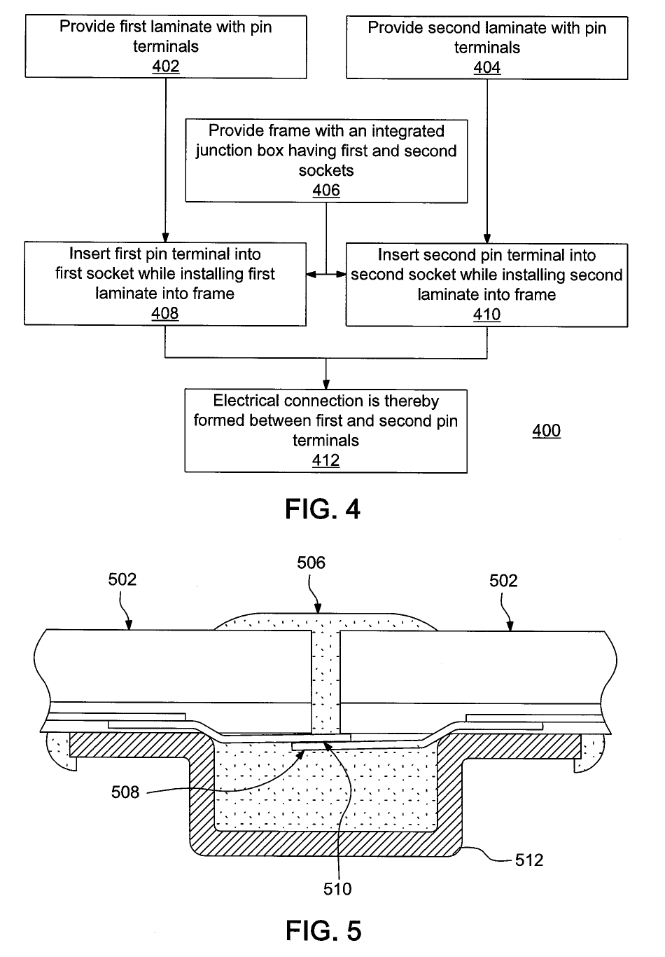

FIG. 4 is a flow chart of a method 400 of manufacturing a PV module assembly with a frame-integrated electrical junction in accordance with the first embodiment of the invention. As shown, first and second PV laminates and a frame for the module assembly are provided (402, 404 and 406, respectively). As provided, the PV laminates are configured with pin terminals, and the frame is configured with an electrical junction box integrated therein. The integrated junction box includes first and second sockets.

A first pin terminal on the first laminate is inserted 408 into the first socket of the integrated junction box. This is done while installing the first laminate into its space into the frame. In addition, a second pin terminal on the second laminate is inserted 410 into the second socket of the integrated junction box. This is done while installing the second laminate into its space in the frame.

In accordance with one embodiment, the junction box is provided with an electrical connection between the first and second sockets. In this case, an electrical connection is formed 412 between the first and second pin terminals once they are inserted into the first and second sockets.

In accordance with one embodiment, the manufacturing of the PV module assembly may include the formation of a plurality of such electrical connections. After completion of the manufacturing of the PV module assembly in the factory, the completed PV module assembly may be transported to the installation site. Alternatively, the PV laminates may be inserted into the frame at the installation site.

FIG. 5 is a cross-sectional view of a frame-integrated electrical junction for a PV module assembly in accordance with a second embodiment of the invention. Shown in FIG. 5 are two PV laminates 502, each laminate 502 including a plurality of solar cells and electrical connections between the solar cells. Bypass diodes may also be embedded within the PV laminates. The specific configuration for the electrical connections and bypass diodes within a PV laminate 502 depends on the specific implementation used.

As further shown, each PV laminate 502 includes at least one module tab 508. The module tab 508 comprises a non-insulated conductive portion which extends out of the PV laminate. In one embodiment, each PV laminate 502 includes two module tabs 508. Each module tab 508 is electrically connected within the PV laminate 502 to at least one of the solar cells. For example, the module tab 508 may be electrically connected to a solar cell in a corner position within the PV laminate 502.

An optional electrical junction box or other stiffening structure (stiffener) 512 is also shown in FIG. 5. As shown, the stiffening structure 512 may be located on one side of the PV laminates 502 and may partially enclose the module tabbing 508.

In accordance with an embodiment of the invention, a solder connection or solder joint 510 may be formed during the manufacturing process in a factory to electrically connect in a permanent manner the module tabbing 508 from the two PV laminates 502. After forming the solder connection 510, an encapsulant (potting) material 506 may be introduced to electrically-insulate and environmentally-protect the module tabbing 508 and solder connection 510. The encapsulant material 506 is preferably elastomeric so as to be resistant to cracking.

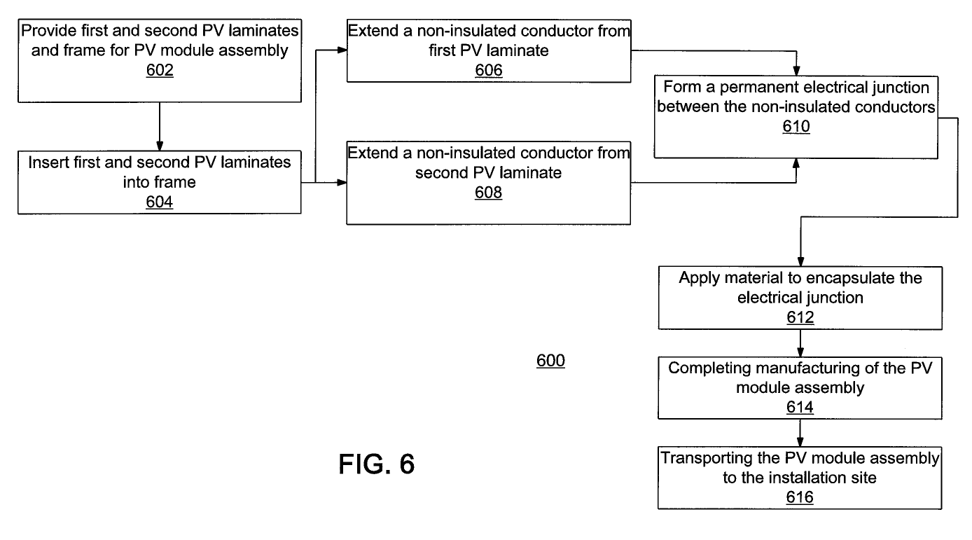

FIG. 6 is a flow chart of a method 600 of manufacturing a PV module assembly with a frame-integrated electrical junction in accordance with the second embodiment of the invention. As shown, first and second PV laminates and a frame for the module assembly are provided 602. As provided, the PV laminates are configured with module tabbing or other non-insulated conductors. The first and second PV laminates are inserted 604 into appropriate spaces in the frame.

As further shown in FIG. 6, the non-insulated conductors are extended from the first and second PV laminates (606 and 608, respectively). Thereafter, a permanent electrical junction is formed 610 between the non-insulated conductors. This electrical junction may be formed, for example, by soldering and may be advantageously performed during manufacturing in a factory setting.

After the electrical junction is formed, the encapsulant material may be applied to enclose 612 the electrical junction. As mentioned above, the encapsulant material is electrically insulating and preferably an elastomeric material.

The manufacturing of the PV module assembly may include the formation of a plurality of such electrical junctions and the encapsulation of those junctions. After completion 614 of the manufacturing of the PV module assembly in the factory, the completed PV module assembly may be transported 616 to the installation site.

The apparatus and methods disclosed herein provide numerous advantages. The integrated junctions allow for the creation of a complete PV module assembly by mechanically and electrically integrating the PV laminates with the frame of the support structure (whether the structure is for a tracker system, a fixed tilt system, a roof system, or other system). This advantageously allows for the elimination of various jumper cables and also provides a more compact overall profile. This also allows for the optimization of the various components as part of the whole assembly, rather than requiring those components to be discrete components.

In addition, the integrated junctions advantageously provide the necessary functionality of a traditional external junction box, while eliminating the need for many external cables. This provides for a reduction of the cost. Furthermore, being able to complete manufacture of the PV module assembly in a factory setting, prior to transportation to an installation site, provides for reduced time and cost of installation. A traditional installation would require the installer to connect various jumper cables to junction boxes in a proper arrangement, while the apparatus and methods disclosed herein provide for the electrical connections between PV laminates to be formed in a factory setting (prior to transportation to the installation site).

While specific embodiments of the present invention have been provided, it is to be understood that these embodiments are for illustration purposes and not limiting. Many additional embodiments will be apparent to persons of ordinary skill in the art reading this disclosure.

What is claimed is:

1. A photovoltaic module assembly manufactured in a factory, the assembly comprising:
a plurality of photovoltaic laminates;
a frame surrounding and supporting each of the photovoltaic laminates in a module; and
a plurality of environmentally-protected electrical junctions that interconnect the photovoltaic laminates.

2. The photovoltaic module assembly of claim 1, further comprising:
electrical junction boxes integrated into the frame which are configured to environmentally protect the electrical junctions.

3. The photovoltaic module assembly of claim 2, wherein each electrical junction box includes a plurality of sockets, and wherein pin terminals of the photovoltaic laminates are configured to be inserted into said sockets.

4. The photovoltaic module assembly of claim 1, further comprising:
an elastomeric encapsulant that surrounds and protects the electrical junctions.

5. The photovoltaic module assembly of claim 4, wherein the electrical junctions comprise a solder connection between metal tabs from adjacently-positioned photovoltaic laminates.

6. The photovoltaic module assembly of claim 5, further comprising:
a stiffener structure which encloses at least a portion of the elastomeric encapsulant.

7. The photovoltaic module assembly of claim 1, further comprising:
inner frame members between individual photovoltaic laminates in the module, wherein the electrical junctions are integrated into the inner frame members.

8. The photovoltaic module assembly of claim 1, further comprising at least one bypass diode integrated into each of the photovoltaic laminates.

9. A method of manufacturing a photovoltaic module assembly, the method comprising:
providing a first photovoltaic laminate with pin terminals electrically connected to solar cells within the first laminate;
providing a second photovoltaic laminate with pin terminals electrically connected to solar cells within the second laminate;
providing a frame with an integrated junction box including first and second sockets, wherein the first and second sockets are electrically connected within the junction box;
inserting a pin terminal of the first photovoltaic laminate into the first socket of the frame while installing the first laminate into the frame; and
inserting a pin terminal of the second photovoltaic laminate into the second socket of the frame while installing the second laminate into the frame.

10. The method of manufacturing of claim 9, wherein an electrical connection is thereby formed between the pin terminals of the first and second photovoltaic laminates.

11. A method of manufacturing a photovoltaic module assembly prior to transportation of the assembly to an installation site, the method comprising:
providing first and second photovoltaic laminates;
providing a frame for the photovoltaic module assembly;
inserting the first and second photovoltaic laminates into the frame;
extending non-insulated conductors from the first and second photovoltaic laminates;
forming an electrical junction between the non-insulated conductors; and
applying a material to encapsulate the electrical junction.

12. The method of claim 11, wherein soldering is used to form the electrical junction.

13. The method of claim 11, further comprising:
completing manufacturing of the photovoltaic module assembly, including the formation of multiple electrical junctions between adjacent photovoltaic laminates; and
transporting the photovoltaic module assembly to an installation site.
